(19) United States
(12) Patent Application Publication
(10) Pub. No.: US 2024/0356540 A1
(43) Pub. Date: Oct. 24, 2024

(54) MULTIPLE SUPPLY LEVEL AREA REDUCTION USING ELECTROSTATIC DISCHARGE SHARING

(71) Applicant: SKYWORKS SOLUTIONS, INC., Irvine, CA (US)

(72) Inventors: Mackenzie Brian Cook, Kanata (CA); Lui Ray Lam, Lexington, MA (US)

(21) Appl. No.: 18/626,649

(22) Filed: Apr. 4, 2024

Related U.S. Application Data
(60) Provisional application No. 63/460,059, filed on Apr. 18, 2023.

(51) Int. Cl. H03K 17/10; H03F 3/24; H03K 17/082

(52) U.S. Cl. CPC H03K 17/102; H03F 3/245; H03K 17/0822; H03F 2200/451

(57) ABSTRACT

Aspects and embodiments disclosed herein include a supply circuit for a radio frequency system comprising a first coupling diode coupled between an input node of a first voltage supply and a first input node of a voltage clamp of the supply circuit, an output of the first coupling diode being coupled to the first input node of the voltage clamp, and a second coupling diode coupled between an input node of a second voltage supply and the first input node of the voltage clamp, an output of the second coupling diode being coupled to the input node of the voltage clamp.

### CROSS-REFERENCE TO RELATED APPLICATIONS

This application claims priority under 35 U.S.C. § 119 (e) to U.S. Provisional Patent Application Ser. No. 63/460,059 titled “MULTIPLE SUPPLY LEVEL AREA REDUCTION USING ELECTROSTATIC DISCHARGE SHARING,” filed Apr. 18, 2023, the entire contents of which is incorporated herein by reference for all purposes.

### BACKGROUND

### Field

The present disclosure relates to protection circuits for electronic systems, and in particular, to protection circuits for protecting radio frequency (RF) circuits from harmful electrical conditions due to multiple power supply sources.

### Description of the Related Technology

In traditional circuits of electronic systems, each supply has its own clamp to ground with a reliability rating required of a pin, i.e., a 5V clamp, a 2.5V clamp, etc., depending on the process with which the circuit was fabricated.

Electrostatic discharge (ESD) clamps occupy a significant area of an integrated circuit (IC). Recent developments in the field require the ICs to have a smaller size in terms of area occupied on a die to reduce costs.

### SUMMARY

The systems, methods and devices of this disclosure each have several aspects, no single one of which is solely responsible for the desirable attributes disclosed herein.

One possibility to address the above-mentioned problems is to use a single ESD clamp if two supplies may use the same clamp and/or allow a low voltage supply to connect at a halfway point of a clamp to satisfy its lower requirements.

In accordance with one aspect, there is provided a supply circuit for a radio frequency system. The supply circuit comprises a first coupling diode coupled between an input node of a first voltage supply and a first input node of a voltage clamp of the supply circuit, an output of the first coupling diode being coupled to the first input node of the voltage clamp, and a second coupling diode coupled between an input node of a second voltage supply and the first input node of the voltage clamp, an output of the second coupling diode being coupled to the input node of the voltage clamp.

In some embodiments, the voltage clamp comprises a plurality of voltage clamps coupled in a series connection.

In some embodiments, the voltage clamp is coupled between the first input node and a voltage reference node of the supply circuit.

In some embodiments, the supply circuit further comprises a first diode coupled between the input node of the first voltage supply and the voltage reference node, an output of the first diode being coupled to the input node of first voltage supply.

In some embodiments, the supply circuit further comprises a second diode coupled between the input node of the second voltage supply and the voltage reference node, an output of the second diode being coupled to the input node of the second voltage supply.

In some embodiments, the supply circuit further comprises a third coupling diode, the third coupling diode being coupled between an input node of a third voltage supply and a second input node of the voltage clamp, an output of the third coupling diode being coupled to an in input node of one of the plurality of voltage clamps.

In some embodiments, the plurality of voltage clamps are coupled between the first input node and a voltage reference node of the supply circuit.

In some embodiments, the supply circuit further comprises a third diode coupled between the input node of the third voltage supply and the voltage reference node, an output of the third diode being coupled to the input node of the third voltage supply.

In some embodiments, each voltage clamp of the plurality of voltage clamps has the same clamping voltage.

In some embodiments, the same clamping voltage is 2.5 Volts.

In accordance with another aspect, there is provided a semiconductor die comprising a semiconductor substrate, an integrated circuit implemented on the semiconductor substrate, and a supply circuit implemented on the semiconductor substrate, the supply circuit including a first coupling diode coupled between an input node of a first voltage supply and a first input node of a voltage clamp of the supply circuit, an output of the first coupling diode coupled to the input node of the voltage clamp, and a second coupling diode coupled between an input node of a second voltage supply and the first input node of the voltage clamp, an output of the second coupling diode being coupled to the input node of the voltage clamp, the supply circuit configured to provide electrostatic discharge protection for at least some of the integrated circuit.

In some embodiments, the voltage clamp comprises a plurality of voltage clamps coupled in a series connection.

In some embodiments, the voltage clamp is coupled between the first input node and a voltage reference node of the supply circuit.

In some embodiments, the semiconductor die further comprises a first diode coupled between the input node of the first voltage supply and the voltage reference node, an output of the first diode being coupled to the input node of first voltage supply.

In some embodiments, the semiconductor die further comprises a second diode coupled between the input node of the second voltage supply and the voltage reference node, an output of the second diode being coupled to the input node of the second voltage supply.

In some embodiments, the semiconductor die further comprises a third coupling diode, the third coupling diode being coupled between an input node of a third voltage supply and an input node of a voltage clamp, an output of the first coupling diode being coupled to an in input node of one of the plurality of voltage clamps.

In some embodiments, the plurality of voltage clamps are coupled between the first input node and a voltage reference node of the supply circuit.

In some embodiments, the semiconductor die further comprises a third diode coupled between the input node of the third voltage supply and the voltage reference node, an output of the third diode coupled to the input node of the third voltage supply.

In some embodiments, each voltage clamp of the plurality of voltage clamps has the same clamping voltage.

In some embodiments, the same clamping voltage is 2.5 Volts.

### BRIEF DESCRIPTION OF THE DRAWINGS

FIG. 1 shows an example configuration where a power amplifier module is provided with power from a power source such as a battery.

FIG. 2 shows an example of an RC-triggered clamp.

FIG. 3 shows that in some examples, a clamp can be implemented based on RC transient detection, with a discharging time prolonged with a partial feedback mechanism.

FIG. 4 shows a chip device that includes a clamp circuit having one or more features as described herein.

FIGS. 5A and 5B show an example of how the clamp circuit of FIG. 4 can be implemented.

FIGS. 6A, 6B and 6C show examples of portions of the chip device where the clamp circuit of FIG. 4 can be implemented.

FIG. 7A shows an example of an early solution in which two similar voltage supplies each have a high voltage clamp which is comprised of two or more stacked lower voltage clamps, and a third lower voltage supply has a lower voltage clamp similar to one of the two or more stacked lower voltage clamps.

FIG. 7B shows an example of a solution in which two similar voltage supplies share a high voltage clamp which is comprised of two or more stacked lower voltage clamps, and a third lower voltage supply has a lower voltage clamp similar to one of the two or more stacked lower voltage clamps.

FIG. 7C shows an example of a solution in which two similar voltage supplies share a high voltage clamp which is comprised of two or more stacked lower voltage clamps, wherein one of the two or more stacked lower voltage clamps is shared with a third lower voltage supply.

FIG. 8 shows that in some examples, a clamp having one or more features as described herein can be implemented on a die.

FIG. 9 shows that in some examples, a die such as the die of FIG. 8 can be implemented in a packaged module.

FIG. 10 depicts an example wireless device having one or more advantageous features described herein.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

In radio-frequency (RF) applications, a clamp is typically implemented on a die, and such a die is typically a part of a module. A clamp may be used to protect, for instance, a power amplifier from harmful electrical conditions such as electrostatic discharges (ESDs) and surges from one or multiple supplies.

By way of an example, a power amplifier may be susceptible to harmful electrical conditions through one or more power amplifier supply pins. Accordingly, a module design (e.g., a power amplifier module) likely includes, for example, either or both of component-level human body model (HBM) and system-level electrostatic overstress (EOS) surge protection. For cost reduction and device miniaturization efforts, the system-level surge suppressor is often removed, which can make concurrent HBM and surge compliant power clamps desirable. Described herein are examples related to surge and HBM performance of a conventional edge-triggered power clamp and gate-coupled NMOS (GCNMOS), where NMOS refers to N-type metal-oxide-semiconductor. Also described herein are examples related to a partial feedback combination clamp and a ballasted RC-triggered clamp, where R refers to resistance and C refers to capacitance.

It is noted that in many applications, ESD and EOS surge protection standards are handled or managed differently between integrated circuit designers and module component designers. Typically, integrated circuit designers plan out an on-chip level ESD protection scheme for HBM, machine model (MM), and charge device model (CDM) qualifications, whereas the EOS surge and International Electrotechnical Commission (IEC) protections are managed through board-level designs (e.g., see C. Duvvury, “New perspectives on component and system ESD”, EDSSC 2014, pp. 1-2). Recently, the foregoing way of handling ESD and EOS surge separately by the two design functions has changed due to a drive in device miniaturization and cost reduction (e.g., see M. Tsai, “An on-chip combo clamp for surge and universal ESD protection in bulk FinFET technology”, EOS/ESD 2016, pp. 1-7; S.-F. Hsu, J.-Y. Jao, “A novel 8 kV on-chip surge protection design in xDSL line driver IC”, IRPS 2015, pp. 1-4; and S. Marum, et. al., “Protecting circuits from the transient voltage suppressor's residual pulse during IEC 61000-4-2 stress”, EOS/EDS 2009, pp. 1-10).

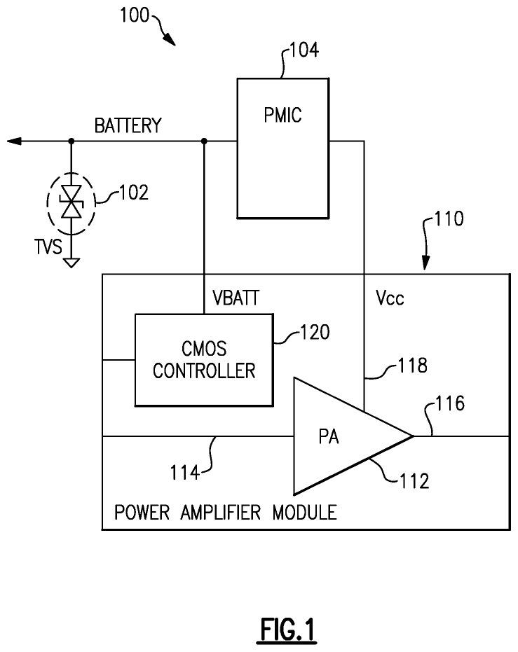

FIG. 1 shows an example of a power management architecture 100 that can be implemented in an RF device such as a wireless device. Such a power management architecture can include a supply voltage Vcc being provided to a power amplifier 112 through a supply path 118. Such a supply voltage (Vcc) can be generated by a power management integrated circuit (PMIC) 104 based on a battery voltage Vbatt.

In FIG. 1, the power amplifier 112 is shown to be configured to receive a signal through an input path 114 and provide an amplified signal through an output path 116. Operation of such a power amplifier can be controlled by a controller 120. Such a controller can receive an input control signal and be powered by, for example, battery voltage Vbatt.

In the example of FIG. 1, the power amplifier 112 is depicted as being a part of a power amplifier module 110. Such a module may also be referred to herein as a chip. It will be understood that a chip can also refer to a die (e.g., a power amplifier die), a packaged module (e.g., a packaged power amplifier module), or some combination thereof.

In RF power amplifier (PA) designs for mobile handset applications, and as depicted in FIG. 1, an off-chip component such as a transient-voltage-suppression (TVS) diode is typically placed along a battery connection to mainly mitigate an EOS surge. In some designs, such a component is removed for cost reduction and device miniaturization. Accordingly, an EOS surge stress is now imposed on on-chip ESD designs.

A rail-based clamp can largely be operated or triggered by RC transient detection and snapback-assisted bipolar action. The RC-triggering design allows large field-effect transistors (FETs) to conduct while detecting an ESD transient. A typical RC-triggering is designed for a duration of under 1 μs, typically just enough for HBM and CDM pulse width. After this, the clamp does not operate.

Described herein are examples of various types of rail-based power clamps. Also described are examples related to a partial feedback power clamp and ballasted RC-triggered clamp as concurrent rail-based clamp solutions for HBM and EOS surge standards.

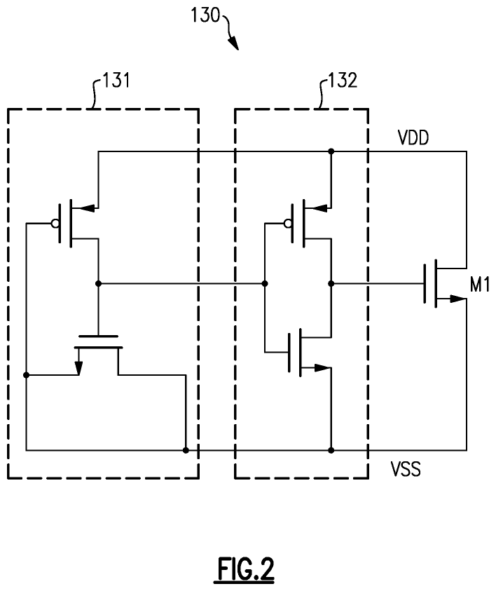

FIG. 2 shows an RC-triggered clamp 130 that typically includes an ESD transient detection RC timer 131, an inverter 132, and an ESD discharging big NFET M1. When an HBM transient is detected at the VDD node, the gate of M1 is immediately pulled up high, and the channel of M1 conducts.

A gate-coupled NMOS triggers from a snap-back bipolar assisted action. Typical triggering voltages can be tuned by the amount of Rgs and Cgd coupling, while each of the fingers of the drain and source active regions can be un-silicided for uniform, or approximately uniform, current distribution under a high ESD current.

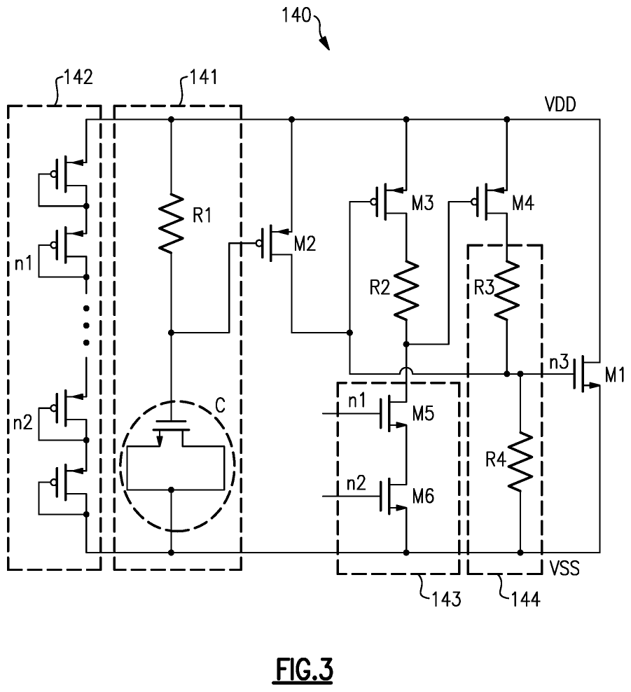

FIG. 3 shows that a clamp 140 can be implemented based on RC transient detection. More particularly, a transient detection circuit 141 can include a resistance R1 and a capacitance C arranged in series between drain and source nodes of an NFET M1, similar to the example of FIG. 2. In some examples, each of the resistance R1 and the capacitance C may or may not be similar to the respective counterpart of FIG. 2.

Referring to FIG. 3, the NFET M1 is shown to have a drain node with voltage VDD, a source node with voltage VSS, and a gate node n3. The drain node (VDD) and the gate node (n3) of M1 are shown to be coupled through a transistor M4 (with the source of M4 being connected to the drain of M1) and a resistance R3, and the source node (VSS) and the gate node (n3) of M1 are shown to be coupled through a resistance R4.

Referring to FIG. 3, the drain node (VDD) and the source node (VSS) of M1 are shown to be coupled through a transistor M3 (with the source of M3 being connected to the drain of M1), a resistance R2, a transistor M5 (with the drain of M5 being connected to the resistance R2), and a transistor M6 (with the drain of M6 being connected to the source of M5, and the source of M6 being connected to the source of M1). The gate of M5 is indicated as a node n1, and the gate of M6 is indicated as n2. A node between the resistance R2 and the transistor M5 is shown to be connected to the gate of M4. Also, the gate of the transistor M3 is shown to be connected to the gate node (n3) of M1. The drain node (VDD) and the gate node (n3) of M1 are shown to be coupled through a transistor M2 (with the source of M2 being connected to the drain of M1, and the drain of M2 being connected to the gate of M1). Accordingly, the drain of M2 is also connected to the gate of M3.

Referring to FIG. 3, a node between the resistance R1 and the capacitance C of the transient detection circuit 141 is shown to be connected to the gate of M2. A voltage divider circuit 142 can be provided between the drain node (VDD) of M1 and the source node (VSS) of M1. Such a voltage divider can include a series of diode-connected FETs, and such diode-connected FETs can be grouped into a first group and a second group. A selected one of the first group of diode-connected FETs can have its gate-drain connected node be connected to the gate node (n1) of the above-referenced transistor M5. Similarly, a selected one of the second group of diode-connected FETs can have its gate-drain connected node be connected to the gate node (n2) of the above-referenced transistor M6.

Configured in the foregoing manner, the clamp 140 can include a surge pulldown functionality generally indicated as 143, and a partial feedback functionality generally indicated as 144. Examples related to such functionalities are described herein in greater detail.

In the clamp 140 of FIG. 3, the discharging time of M1 can be prolonged due to a partial feedback provided at least in part by the partial feedback block 144. For example, when an RC transient is below a time constant (e.g., within the duration of HBM waveform at the VDD node), M2 turns on, causing M3 to turn off, and then M4 turns on to enable M1, the big NFET, to discharge the HBM current (e.g., from VDD to VSS). When the RC transient is greater than the time constant of the RC detection circuit (e.g., the circuit is detecting the tens of us surge stress waveform at the VDD node), M5 and M6 are activated while n3 node of M1 is pulled low. The n3 node is partially fed back and pulled high from M4 turning on by M5 and M6 surge pull down.

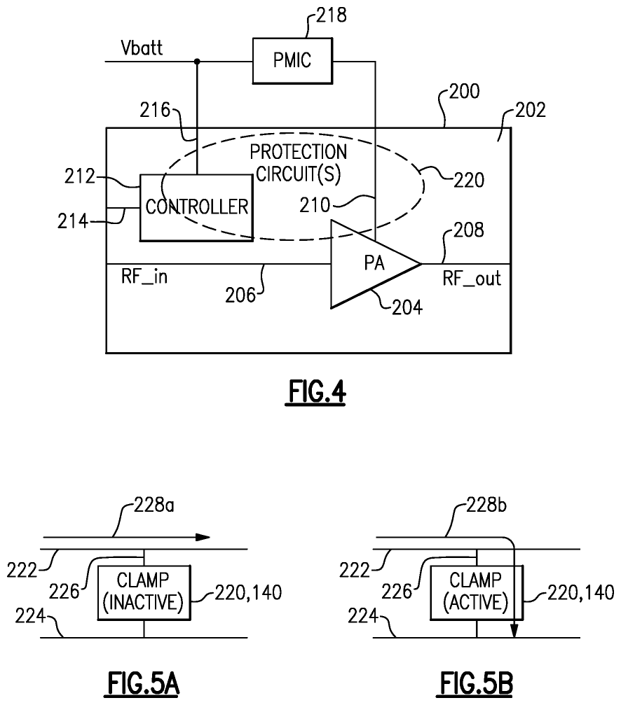

FIG. 4 shows that in some examples, one or more protection circuits 220 can be implemented as part of a radio-frequency chip device 200. As described herein, such a chip device can be a semiconductor die, a packaged module having one or more die, or some combination thereof.

In the example of FIG. 4, the chip device 200 can include a substrate 202. If the chip device 200 is a semiconductor die, the substrate 202 can be a semiconductor substrate. If the chip device 200 is a packaged module, the substrate 202 can be a packaging substrate.

In the example of FIG. 4, the implementation of one or more protection circuits 220 can allow removal of a protection circuit outside of the chip device 200. For example, in the context of the architecture of FIG. 1, the TVS 102 that is implemented outside of the power amplifier module 110 can be eliminated from the power management architecture 100.

It is noted that the example of FIG. 4 is implemented in a radio-frequency application similar to the example of FIG. 1. Accordingly, the chip device 200, having a substrate 202, is shown to include a power amplifier 204 configured to amplify an input signal RF_in received through an input path 206, and generate an output signal RF_out through an output path 208. Operation of such a power amplifier can be controlled by a controller 212 (e.g., a CMOS controller) configured to receive one or more input signals such as a control signal through one or more input pins (depicted as 214).

As shown in FIG. 4, the power amplifier 204 can be provided with a supply voltage through a supply path 210 that is electrically connected to a supply pin on the chip device 200. Such a supply pin is shown to be connected to a supply voltage source, such as a battery voltage (Vbatt) through a power management integrated circuit (PMIC) 218.

As also shown in FIG. 4, the controller 212 can be provided with power through a supply path 216 that is electrically connected to a supply pin on the chip device 200. Such a supply pin is shown to be connected to a supply voltage source such as a battery voltage (Vbatt).

FIG. 4 shows that in some examples, the chip device 200 can include one or more clamp circuits having one or more features as described herein. Such clamp circuit(s) can be implemented at different locations of the chip device 200. Accordingly, in FIG. 4 such clamp circuit(s) are depicted as 220. Non-limiting examples of implementations of such clamp circuit(s) are described herein in greater detail.

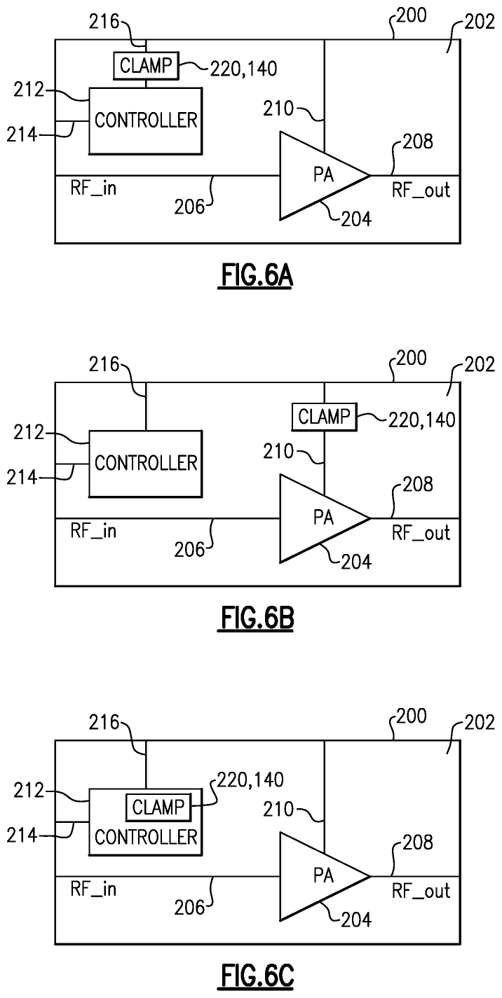

FIGS. 5A and 5B show an example of how each of the clamp circuit(s) of FIG. 4 can be implemented within the chip device (200 in FIG. 4). In some examples, a clamp circuit (indicated as 220, 140) such as the clamp circuit 140 of FIG. 3 can be implemented along a first node 222 so as to allow an electrical current to be re-directed to a second node 224. The first node 222 can be, for example, a supply node where a supply voltage is present and also susceptible to an electrical disturbance (e.g., ESD and/or surge).

In the example of FIG. 4, such a first node (222) can be a node coupled to either or both of the supply pins 210, 216. In the context of the clamp circuit 140 of FIG. 3, the VDD node of the clamp circuit 140 can be coupled to the first node 222 of FIGS. 5A and 5B.

Referring to FIG. 4 and to FIGS. 5A and 5B, the second node 224 can be a node where a re-directed current associated with the electrical disturbance can be directed. Such a second node can be, for example, a ground node. In the context of the clamp circuit 140 of FIG. 3, the VSS node of the clamp circuit 140 can be coupled to the second node 224 of FIGS. 5A and 5B.

FIGS. 5A and 5B show the clamp circuit (220, 140) in its inactive state and active state, respectively. When the clamp circuit (220, 140) is inactive (FIG. 5A), an electrical current 228a present at the first node 222 is allowed to continue to its destination load (e.g., to the right along the node 222). However, when the clamp circuit (220, 140) is activated as described herein, an electrical current 228b, including a current associated with an electrical disturbance (e.g., ESD and/or surge) is re-directed from the first node 222 to the second node 224 through the clamp circuit (220, 140), so as to prevent the harmful electrical disturbance from reaching the destination load.

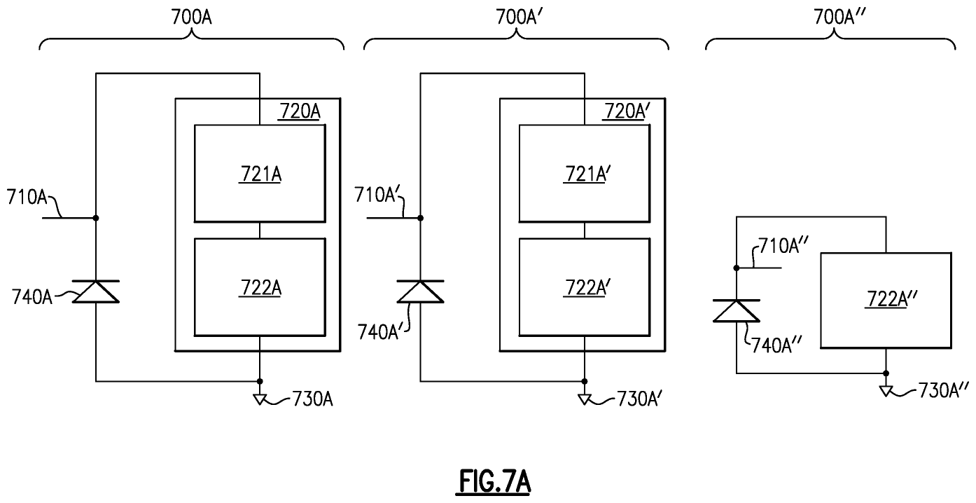

FIGS. 6A-6C show examples of how a clamp circuit (220, 140) having one or more features as described herein can be implemented within the chip device 200 of FIG. 4 and FIGS. 5A and 5B.

In some examples, a clamp circuit (220, 140) can be implemented so as to be associated with a controller 212 of the chip device 200. For example, and as shown in FIG. 6A, a clamp circuit (220, 140) can be implemented along the supply path 216 for the controller 212, but generally outside of what can be considered to be the controller 212. In another example, and as shown in FIG. 6C, a clamp circuit (220, 140) can be implemented as a part of what can be considered to be the controller 212.

In some examples, a clamp circuit (220, 140) can be implemented so as to be associated with a power amplifier 204 of the chip device 200. For example, and as shown in FIG. 6B, a clamp circuit (220, 140) can be implemented along the supply path 210 for the power amplifier 204, but generally outside of what can be considered to be the power amplifier 204. In another example, a clamp circuit (220, 140) can be implemented as a part of what can be considered to be the power amplifier 204.

In some examples, the clamp circuit (220, 140) of FIG. 4 to FIG. 6C may or may not include a ballasting feature described herein. Similarly, in some examples, the clamp circuit 140 of FIG. 3 may or may not include a ballasting feature.

As described herein, a partial feedback clamp and/or ballasted RC-triggered clamp can provide a number of desirable features. Examples of analysis and comparison indicate that surge performance of ballasted RC clamp greatly improves due to the ballasting while keeping HBM performance reasonable. In addition, DC leakage current remains comparable to the existing edge-triggered clamp. The partial feedback combination clamp can also be a substitute with comparable HBM performance, reasonable high surge rating, and two orders degradation in standby leakage current.

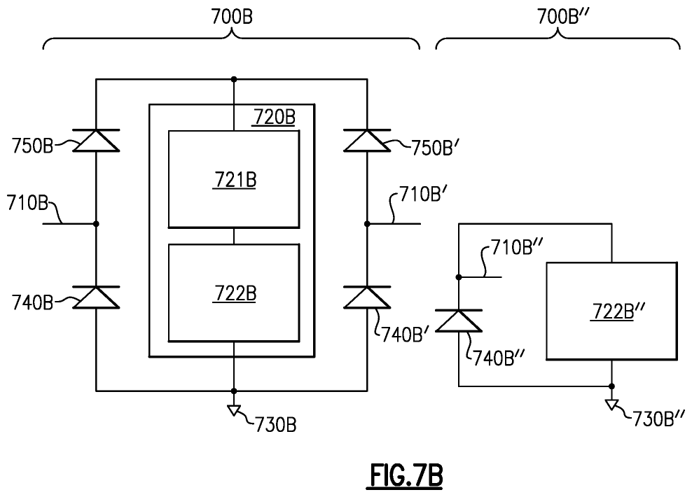

FIG. 7A shows an example of an early solution in which two similar voltage supplies 710A and 710A′ each have a high voltage clamp 720A and 720A′ comprised of two or more stacked lower voltage clamps 721A to 722A and 721A′ to 722A′, and a third lower voltage supply 700A″ has a lower voltage clamp 722A″ similar to one of the two or more stacked lower voltage clamps 722A and 722A′. A voltage supply may be a digital supply voltage or a battery.

A first supply circuit 700A comprises a first voltage supply 710A, a first voltage clamp 720A, a first voltage reference node 730A, and a first diode 740A.

The first voltage supply 710A may be configured to provide a first supply voltage.

The first voltage clamp 720A may be configured for clamping a first clamping voltage, 5V, for example. The first voltage clamp 720A may comprise a plurality of voltage clamps 721A to 722A, the plurality of voltage clamps 721A to 722A being stacked for clamping the first clamping voltage. Each of the plurality of voltage clamps may be configured for clamping a respective clamping voltage, the respective clamping voltage being equal or less than the first clamping voltage, 2.5V, for example. The plurality of voltage clamps may be stacked in series. The clamping voltage of each of the plurality of voltage clamps may be the same. The plurality of voltage clamps may have two clamps, where the clamping voltages of the said two clamps are different.

A second supply circuit 700A′ comprises a second voltage supply 710A′, a second voltage clamp 720A′, a second voltage reference node 730A′, and a second diode 740A′.

The second voltage supply 710A′ may be configured to provide a second supply voltage. The first supply voltage of the first supply circuit 700A and the second supply voltage of the second supply circuit 700A′ may be approximately the same.

The second voltage clamp 720A′ may be configured for clamping a second clamping voltage, 5V, for example. The first clamping voltage of the first voltage clamp and the second clamping voltage of the second voltage clamp may be approximately the same.

The second voltage clamp 720A′ may comprise a plurality of voltage clamps 721A′ to 722A′, the plurality of voltage clamps 721A′ to 722A′ being stacked for clamping the second clamping voltage. Each of the plurality of voltage clamps may be configured for clamping a respective clamping voltage, the respective clamping voltage being equal or less than the second clamping voltage, 2.5V, for example. The plurality of voltage clamps may be stacked in series. The clamping voltage of each of the plurality of voltage clamps may be the same. The plurality of voltage clamps may have two clamps, where the clamping voltages of the said two clamps are different.

A third supply circuit 700A″ comprises a third voltage supply 710A″, a third voltage clamp 722A″, a third voltage reference node 730A″, and a third diode 740A″.

The third voltage supply 710A″ may be configured to provide a third supply voltage. The first supply voltage of the first supply circuit 700A and/or the second supply voltage of the second supply circuit 700A′ may be greater than the third supply voltage of the third voltage supply 710A″.

The third voltage clamp 720A″ may be configured for clamping a third clamping voltage, 2.5V, for example. The first clamping voltage of the first voltage clamp and the second clamping voltage of the second voltage clamp may be greater than the third clamping voltage of the third voltage clamp.

The third voltage clamp 720A″ may comprise a plurality of voltage clamps (not shown in FIG. 7A), the plurality of voltage clamps being stacked for clamping the third clamping voltage. Each of the plurality of voltage clamps may be configured for clamping a respective clamping voltage, the respective clamping voltage being equal or less than the third clamping voltage, 1.5V, for example. The plurality of voltage clamps may be stacked in series. The clamping voltage of each of the plurality of voltage clamps may be the same. The plurality of voltage clamps may have two clamps, where the clamping voltages of the said two clamps are different.

FIG. 7B shows an example of a solution in which two similar voltage supplies 710B and 710B′ share a high voltage clamp 720B which is comprised of two or more stacked lower voltage clamps 721B to 722B, and a third lower voltage supply 710B″ has a lower voltage clamp 722B″ similar to one of the two or more stacked lower voltage clamps 721B to 722B.

A first supply circuit 700B comprises a first voltage supply 710B, a second voltage supply 710B′, a first voltage clamp 720B, a first voltage reference node 730B, a first diode 740B, a second diode 740B′, a first coupling diode 750B, and a second coupling diode 750B′.

The first voltage supply 710B may be configured to provide a first supply voltage. The first coupling diode 750B may be coupled between the first voltage supply 710B and the first voltage clamp 720B. The first diode 740B may be coupled between the first voltage supply 710B and the first voltage reference node 730B.

The second voltage supply 710B′ may be configured to provide a second supply voltage. The first supply voltage and the second supply voltage may be approximately the same, 5V, for example. The second coupling diode 750B′ may be coupled between the second voltage supply 710B′ and the first voltage clamp 720B. The first coupling diode 750B and the second coupling diode 750B′ may be directly coupled to each other. The first voltage clamp 720B may be coupled between said direct coupling and the first voltage reference node 730B. The second diode 740B′ may be coupled between the second voltage supply 710B′ and the first voltage reference node 730B.

The first voltage clamp 720B may be configured for clamping a first clamping voltage, 5V, for example. The first voltage clamp 720B may comprise a plurality of voltage clamps 721B to 722B, the plurality of voltage clamps 721B to 722B being stacked for clamping the first clamping voltage. Each of the plurality of voltage clamps may be configured for clamping a respective clamping voltage, the respective clamping voltage being equal or less than the first clamping voltage, 2.5V, for example. The plurality of voltage clamps may be stacked in series. The clamping voltage of each of the plurality of voltage clamps may be the same. The plurality of voltage clamps may have two clamps, where the clamping voltages of the said two clamps may be the same or may be different.

A second supply circuit 700B″ comprises a third voltage supply 710B″, a second voltage clamp 722B″, a second voltage reference node 730B″, and a third diode 740B″.

The third voltage supply 710B″ may be configured to provide a third supply voltage. The first supply voltage and the second supply voltage of the first supply circuit 700B may be greater than the third supply voltage of the third voltage supply 710B″. The third diode 740B″ may be coupled between the third voltage supply 710B″ and the second voltage reference node 730B″.

The second voltage clamp 722B″ may be configured for clamping a second clamping voltage, 2.5V, for example. The first clamping voltage of the first voltage clamp may be greater than the second clamping voltage of the second voltage clamp.

The second voltage clamp 722B″ may comprise a plurality of voltage clamps (not shown in FIG. 7B), the plurality of voltage clamps being stacked for clamping the third clamping voltage. Each of the plurality of voltage clamps may be configured for clamping a respective clamping voltage, the respective clamping voltage being equal or less than the third clamping voltage, 0.5V, for example. The plurality of voltage clamps may be stacked in series. The clamping voltage of each of the plurality of voltage clamps may be the same. The plurality of voltage clamps may have two clamps, where the clamping voltages of the said two clamps may be the same or may be different.

FIG. 7C shows an example of a solution in which two similar voltage supplies 710C to 710C′ share a high voltage clamp 720′ which is comprised of two or more stacked lower voltage clamps 721C to 722C, wherein one, 722C, of the two or more stacked lower voltage clamps 721C to 722C is shared with a third lower voltage supply 710C″.

A supply circuit 700C comprises a first voltage supply 710C, a second voltage supply 710C′, and a third voltage supply 710C″, a first voltage clamp 720C, a first voltage reference node 730C, a first diode 740C, a second diode 740C′, a third diode 740C″, a first coupling diode 750C, a second coupling diode 750C′, and a third coupling diode 750C″.

The first voltage supply 710C may be configured to provide a first supply voltage. The first coupling diode 750C may be coupled between the first voltage supply 710C and the first voltage clamp 720C. The first diode 740C may be coupled between the first voltage supply 710C and the first voltage reference node 730C.

The second voltage supply 710C′ may be configured to provide a second supply voltage. The first supply voltage and the second supply voltage may be approximately the same, 5V, for example. The second coupling diode 750C′ may be coupled between the second voltage supply 710C′ and the first voltage clamp 720C. The first coupling diode 750C and the second coupling diode 750C′ may be directly coupled to each other. The first voltage clamp 720C may be coupled between said direct coupling and the first voltage reference node 730C. The second diode 740C′ may be coupled between the second voltage supply 710C′ and the first voltage reference node 730C.

The first voltage clamp 720C may be configured for clamping a first clamping voltage, 5V, for example. The first voltage clamp 720C may comprise a plurality of voltage clamps 721C to 722C, the plurality of voltage clamps 721C to 722C being stacked for clamping the first clamping voltage. Each of the plurality of voltage clamps may be configured for clamping a respective clamping voltage, the respective clamping voltage being equal or less than the first clamping voltage, 2.5V, for example. The plurality of voltage clamps may be stacked in series. The clamping voltage of each of the plurality of voltage clamps may be the same. The plurality of voltage clamps may have two clamps, where the clamping voltages of the said two clamps may be the same or may be different.

The third coupling diode 750C″ may be coupled between a series connection of the plurality of voltage clamps and the third voltage supply 710C″. The third diode 740C″ may be coupled between the third voltage supply 710C″ and the first voltage reference node 730C.

This technique allows a designer to save significant area by using a single high voltage clamp between all the supply pins on a die, an N times reduction where N is the number of supplies.

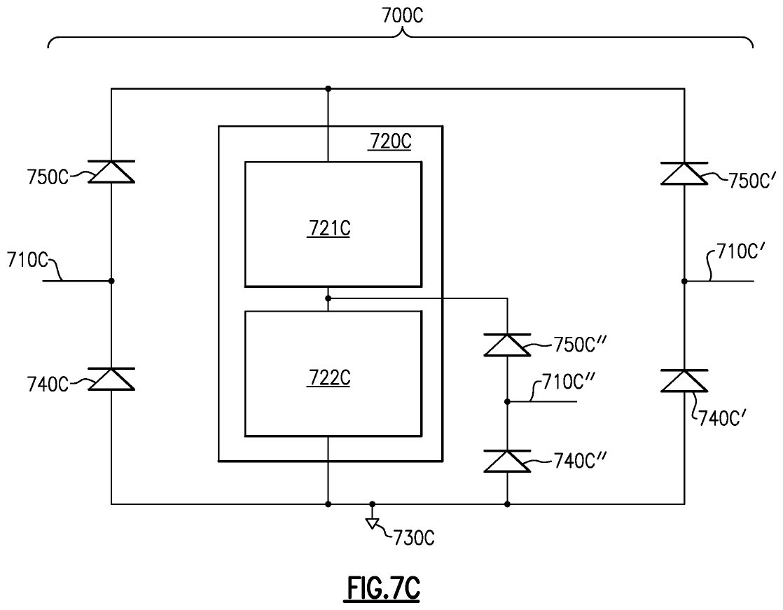

FIG. 8 shows that in some examples, a clamp (220, 140) having one or more features as described herein can be implemented on a die 300. Such a die can include a semiconductor substrate 302. In some examples, the same die 300 can also include a power amplifier circuit 204. In some examples, the die 300 can be the chip device 200 of FIG. 4.

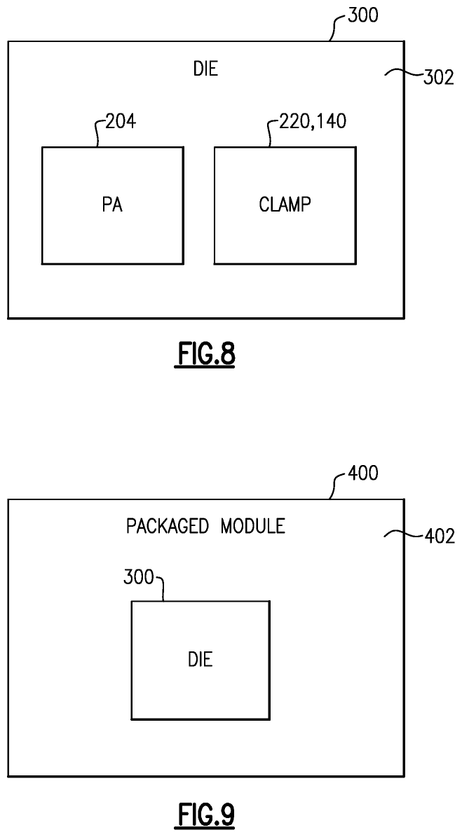

FIG. 9 shows that in some examples, a die 300 such as the die of FIG. 8 can be implemented in a packaged module 400. Such a packaged module can include a packaging substrate 402 configured to receive a plurality of components. At least some of the components mounted on the packaging substrate 402 can include a die 300, such as the die 300 of FIG. 8.

In some examples, a packaged module can be the chip device 200 of FIG. 4. Such a packaged module can include a die with or without a clamp having one or more features as described herein.

In some implementations, a device and/or a circuit having one or more features described herein can be included in an RF device such as a wireless device. Such a device and/or a circuit can be implemented directly in the wireless device, in a modular form as described herein, or in some combination thereof. In some examples, such a wireless device can include, for example, a cellular phone, a smart-phone, a hand-held wireless device with or without phone functionality, a wireless tablet, etc.

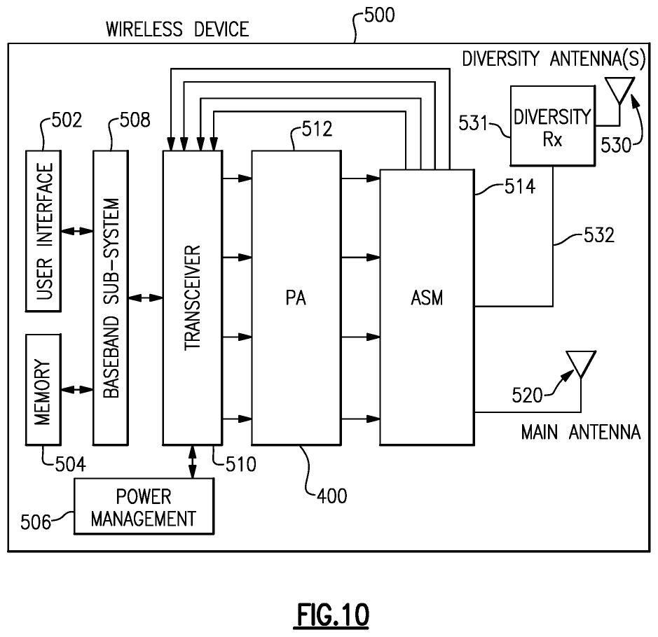

FIG. 10 depicts an example wireless device 500 having one or more advantageous features described herein. In some examples, a module 400 that includes one or more power amplifiers can also include one or more clamps having one or more features as described herein.

In the example of FIG. 10, power amplifiers (PAs) are depicted in a PA module 512; however, it will be understood that such power amplifiers can be implemented in one or more functional blocks, one or more devices such as die or modules, etc. Such power amplifiers can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 is also shown to be connected to a power management component 506 that is configured to manage power for the operation of the wireless device 500. Such power management can also control operations of the baseband sub-system 508 and other components of the wireless device 500.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example of FIG. 10, a diversity receive (DRx) module 531 can be implemented between one or more diversity antennas (e.g., diversity antenna 530) and a front-end module. Such a configuration can allow an RF signal received through the diversity antenna 530 to be processed (in some examples, including amplification by an LNA) with little or no loss of and/or little or no addition of noise to the RF signal from the diversity antenna 530. Such processed signal from the DRx module 531 can then be routed to the front-end module through one or more signal paths. In some examples, the wireless device 500 may or may not include the foregoing DRx functionality.

In the example of FIG. 10, a plurality of antennas can be configured to, for example, facilitate transmission of RF signals from the PA module 512. In some examples, receive operations can also be achieved through some or all of the antennas.

Any of the principles and advantages discussed herein can be applied to other systems, not just to the systems described above. The elements and operations of the various examples described above can be combined to provide further examples. Some of the examples described above have provided examples in connection with power amplifiers and/or wireless communications devices. However, the principles and advantages of the examples can be used in connection with any other systems, apparatus, or methods that benefit could from any of the teachings herein. For instance, any of the principles and advantages discussed herein can be implemented in connection with detecting power from one of a plurality of different signal paths of which only one is active at a time. Any of the principles and advantages discussed herein can be implemented in association with RF circuits configured to process signals in a range from about 30 kilohertz (kHz) to 300 gigahertz (GHz), such as in a range from about 450 MHz to 6 GHZ.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an car piece or smart eyeglasses or virtual reality equipment, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, IoT radios, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain examples include, while other examples do not include, certain features, elements and/or states. The word “coupled,” as generally used herein, refers to two or more elements that may be either directly coupled, or coupled by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain examples have been described, these examples have been presented by way of example only, and are not intended to limit the scope of the disclosure. Indeed, the novel devices, modules, wireless communication devices, apparatus, methods, and systems described herein may be embodied in a variety of other forms. Furthermore, various omissions, substitutions and changes in the form of the devices, modules, wireless communication devices, apparatus, methods, and systems described herein may be made without departing from the spirit of the disclosure. For example, while blocks are presented in a given arrangement, alternative examples may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various examples described above can be combined to provide further examples. The accompanying claims and their equivalents are intended to cover such forms or modifications as would fall within the scope and spirit of the disclosure.

What is claimed is:

1. A supply circuit for a radio frequency system, the supply circuit comprising:
a first coupling diode coupled between an input node of a first voltage supply and a first input node of a voltage clamp of the supply circuit, an output of the first coupling diode being coupled to the first input node of the voltage clamp; and
a second coupling diode coupled between an input node of a second voltage supply and the first input node of the voltage clamp, an output of the second coupling diode being coupled to the input node of the voltage clamp.

2. The supply circuit of claim 1 wherein the voltage clamp comprises a plurality of voltage clamps coupled in a series connection.

3. The supply circuit of claim 2 wherein the voltage clamp is coupled between the first input node and a voltage reference node of the supply circuit.

4. The supply circuit of claim 3 further comprising a first diode coupled between the input node of the first voltage supply and the voltage reference node, an output of the first diode being coupled to the input node of first voltage supply.

5. The supply circuit of claim 4 further comprising a second diode coupled between the input node of the second voltage supply and the voltage reference node, an output of the second diode being coupled to the input node of the second voltage supply.

6. The supply circuit of claim 5 further comprising a third coupling diode, the third coupling diode being coupled between an input node of a third voltage supply and a second input node of the voltage clamp, an output of the third coupling diode being coupled to an in input node of one of the plurality of voltage clamps.

7. The supply circuit of claim 6 wherein the plurality of voltage clamps are coupled between the first input node and a voltage reference node of the supply circuit.

8. The supply circuit of claim 7 further comprising a third diode coupled between the input node of the third voltage supply and the voltage reference node, an output of the third diode being coupled to the input node of the third voltage supply.

9. The supply circuit of claim 2 wherein each voltage clamp of the plurality of voltage clamps has the same clamping voltage.

10. The supply circuit of claim 9 wherein the same clamping voltage is 2.5 Volts.

11. A semiconductor die comprising:
a semiconductor substrate;
an integrated circuit implemented on the semiconductor substrate; and
a supply circuit implemented on the semiconductor substrate, the supply circuit including a first coupling diode coupled between an input node of a first voltage supply and a first input node of a voltage clamp of the supply circuit, an output of the first coupling diode coupled to the input node of the voltage clamp, and a second coupling diode coupled between an input node of a second voltage supply and the first input node of the voltage clamp, an output of the second coupling diode being coupled to the input node of the voltage clamp, the supply circuit configured to provide electrostatic discharge protection for at least some of the integrated circuit.

12. The semiconductor die of claim 11 wherein the voltage clamp comprises a plurality of voltage clamps coupled in a series connection.

13. The semiconductor die of claim 12 wherein the voltage clamp is coupled between the first input node and a voltage reference node of the supply circuit.

14. The semiconductor die of claim 13 further comprising a first diode coupled between the input node of the first voltage supply and the voltage reference node, an output of the first diode being coupled to the input node of first voltage supply.

15. The semiconductor die of claim 14 further comprising a second diode coupled between the input node of the second voltage supply and the voltage reference node, an output of the second diode being coupled to the input node of the second voltage supply.

16. The semiconductor die of claim 15 further comprising a third coupling diode, the third coupling diode being coupled between an input node of a third voltage supply and an input node of a voltage clamp, an output of the first coupling diode being coupled to an in input node of one of the plurality of voltage clamps.

17. The semiconductor die of claim 16 wherein the plurality of voltage clamps are coupled between the first input node and a voltage reference node of the supply circuit.

18. The semiconductor die of claim 17 further comprising a third diode coupled between the input node of the third voltage supply and the voltage reference node, an output of the third diode coupled to the input node of the third voltage supply.

19. The semiconductor die of claim 12 wherein each voltage clamp of the plurality of voltage clamps has the same clamping voltage.

20. The semiconductor die of claim 19 wherein the same clamping voltage is 2.5 Volts.
